(19) United States
(12) Patent Application Publication
(10) Pub. No.: US 2021/0399153 A1
(43) Pub. Date: Dec. 23, 2021

(54) OPTICALLY-TRANSPARENT SEMICONDUCTOR BUFFER LAYERS AND STRUCTURES EMPLOYING THE SAME

(71) Applicant: ARRAY PHOTONICS, INC., Tempe, AZ (US)

(72) Inventors: Philip DOWD, Gilbert, AZ (US); Jacob THORP, Phoenix, AZ (US); Michael SHELDON, Marana, AZ (US); Ferran SUAREZ, Chandler, AZ (US)

(21) Appl. No.: 17/278,119

(22) PCT Filed: Oct. 1, 2019
(86) PCT No.: PCT/US2019/054014

§ 371 Date: Mar. 19, 2021

Related U.S. Application Data
(60) Provisional application No. 62/740,614, filed on Oct. 3, 2018.

(51) Int. Cl. H01L 31/0687; H01L 31/0693

(52) U.S. Cl. CPC H01L 31/06875; H01L 31/0693

(57) ABSTRACT

Semiconductor structures including optically-transparent metamorphic buffer regions, devices employing such structures, and methods of fabrication. The optically-transparent metamorphic buffer is grown to provide a lattice constant transition between a smaller lattice constant and a larger lattice constant (or vice-versa), allowing materials with two different lattice constants to be monolithically integrated. Such buffer layer may include at least two elements from group V of the periodic table. The optically-transparent metamorphic buffer region may include digital-alloy superlattice structure (s) to confine material defects to the metamorphic buffer layer, and improve electrical properties of the metamorphic buffer layer, thereby improving the electronic properties of electronic devices such as optoelectronic devices and photovoltaic cells. Photonic devices such as solar cells and optical detectors containing such semiconductor structures.

### CROSS-REFERENCE TO RELATED APPLICATIONS

This application claims priority from and benefit of the U.S. Provisional Patent Application No. 62/740,614 filed on Oct. 3, 2018, the entire disclosure of which is incorporated by reference herein.

### TECHNICAL FIELD

The present invention relates to layered structures containing optically-transparent semiconductor metamorphic buffer layers (or buffers, for short) judiciously configured to allow these buffers to be reliably grown on an underlying substrate that has either a small lattice constant or a large lattice constant (as compared to the lattice constant of the buffer layer(s)). Regardless of the specific value of the lattice constant of the underlying substrate, implementations of the idea of the invention facilitate a change or transition of the lattice constant from that corresponding to the lattice constant of the underlying substrate to another value (via either increase or decrease of the lattice constant throughout the process of grown of the buffer on the underlying substrate). The invention further relates to semiconductor devices that include a) a light-emitting or, alternatively, a light-absorbing region that overlays the buffer, on the one hand, and/or b) a light-emitting or light-absorbing region that underlays the buffer, on the other hand.

### RELATED ART

compound semiconductor materials are widely used in fabrication of semiconductor optoelectronic devices such as emitters, detectors, and modulators (and for a variety of applications), as well as in the fabrication of multijunction solar cells. While various semiconductor alloys can be used to emit or absorb light in different wavelength ranges (depending on the bandgap and structure of such alloys), different alloys may possess different lattice constants within a wide spatial range. A need to produce high-quality materials and devices with such diversity of material lattice constants compels the user to form or grow these alloys on specific and often different substrates.

For example, for operation at visible and near-infrared (NIR) wavelengths (typically, in the range from about 0.75 to about 1 micron), or short wavelength infrared (SWIR) wavelengths (typically, within the range from about 1 micron to about 2.5 microns), devices can generally be formed using epitaxial growth techniques on a substrate such as GaAs. Materials including AlGaAs, InGaAs, InAlP, InGaP, and dilute nitrides (such as GaInNAsSb, for example) can be grown lattice-matched to a chosen substrate (such as a GaAs substrate, for example), to ensure high quality of the grown layers with low levels of material defects. For operation at telecommunications wavelengths (at about 1.3 μm and/or 1.55 μm), Indium Gallium Arsenide (InGaAs) alloys are typically used, and are grown to be lattice-matched to InP substrates to achieve and similarly ensure high-quality results. Devices operating at longer wavelengths, such as the mid-wavelength infrared (MWIR) and long-wave infrared (LWIR) ranges (that is, from about 3 microns to about 5 microns; and from about 8 microns to about 12 microns, respectively) are generally formed by growth of appropriately-chosen materials on a substrate made of, for instance, GaSb. (For example, related art discussed the detectors that utilize materials with type-II superlattices.)

While substrates made of materials such as InP and GaSb are used in practice, such use involves a number of operational limitations that include high substrate cost, limited diameters of grown wafer diameters (and associated quality shortcomings characterizing wafers of large diameters), as well as low yields due to fragility of the InP/GaSb substrates. Both from manufacturing and economic perspectives, gallium arsenide (GaAs) presents a better substrate choice. At the same time, however, the large lattice mismatch between GaAs and many of the semiconductor alloys, required to be grown to produce the IR-range devices, results in poor quality of the grown materials if such materials are directly deposited on the GaAs substrate. This compromises the electrical and/or optical performance of the resulting devices.

An alternative to forming IR-devices on a substrate such as GaSb may be provided by 1) growing a buffer layer on a different substrate (for example, a GaAs substrate) such as to transition the value of the material lattice constant—throughout the buffer layer—from that of GaAs to that of GaSb, and then 2) forming the device by depositing required materials on an “outer” surface of the buffer layer that is characterized by a lattice constant approximating that of GaSb. Such buffer can be configured to utilize a bulk layer of GaSb, for example, (as described by B.-M. Nguyen et al., in “Demonstration of midinfrared type-II InAs/GaSb superlattice photodiodes grown on GaAs substrate”, App. Phys. Lett. 94, 223506 (2009), and by U. Serincan et el., in “Direct growth of type II InAs/GaSb superlattice MWIR photodetector on GaAs substrate”, Superlattices and Microstructures 120, pp15-21 (2018)).

Notably, the related art clearly indicates that such buffers are designed based only and solely on considerations of structural and electrical properties in mind, and without taking into account the optical properties of the buffers (which properties can affect the optical absorption in an overlying or underlying absorbing layer in a device such as a multicolor photodetector or a multijunction photovoltaic cell, for example). Under the accepted by related art and followed by industry considerations of design of a buffer layer—which exclude and do not take into account the optical properties of the buffer layer—a person of skill will readily recognize this current approach to design of buffer layers to be operationally deficient. Indeed, since a given buffer layer is typically absorbing in a certain wavelength range, the performance of a device (e.g., a multicolor photodetector or a multijunction solar cell) fabricated by integrating, onto the same buffer layer, absorbing regions with different absorption spectra and with different lattice constants can be detrimentally affected by the parasitic absorption in the so-formed buffer layer.

A skilled artisan will appreciate, therefore, that although it is conceivable to design a device that is based on one material system while operating at wavelengths typically associated with another material system (in one example—a GaAs-based quantum cascade laser), a set of different operational wavelengths (those emitted by a resulting active device or absorbed by the resulting passive device) is understandably and inevitably limited when a given structure is grown with a specific lattice constant. Accordingly, to achieve a broad spectral range of operation of a monolithic device formed with materials possessing a single lattice constant can be challenging, and either buffer layers are required, or wafer bonding of different materials with different lattice constants is required to attempt to make it happen.

Another substrate used for multijunction photovoltaic devices employs Ge—this is a group IV substrate that also forms a subcell (or junction) of the device. However, completing a process of successful growth of III-V materials on such a substrate is known to present substantial challenges. GaSb is a material with a bandgap similar to that of Ge and is currently being investigated to determine its applicability to fabrication of multijunction solar cells. Notably, the lattice constant of GaSb is much larger than those of GaAs or Ge, making the integration of GaSb materials into existing multijunction solar cells substantially complicated and requiring either the use of a suitable buffer layer, or the use of wafer bonding.

In other multijunction solar cells structures, InGaAs or AlInGaAs metamorphic buffer layers may be used to allow materials with different lattice constants to be integrated. However, the bandgap of such buffer can result in parasitic absorption, thereby limiting the bandgap and composition for a lattice-mismatched subcell layer.

Related art also demonstrated wafer bonding of large-area III-V material substrates. And yet, the main shortcoming of the bonding process—specifically, a need to strictly observe bonding conditions—remains. In addition, layers of materials may be required to be grown on more than one substrate (including a substrate such as GaSb), and possibly with a substrate removal step to arrive at a final device based on bonding, thereby further complicating the manufacturing process. Moreover, the wafer bonding process can introduce defects into structures at the interface between the two bonded wafers, which in turn can affect the electrical and optical performance of wafer-bonded devices.

While an attempt of a multijunction solar cell employing both a wafer bonding process (to integrate a GaSb based subcell) and a metamorphic AlInGaAs buffer (to achieve the integration of an InGaAs subcell with additional subcells having a lattice constant approximately equal to that of GaAs) has been disclosed (in, for example, U.S. 2015/0372179), such attempt expressly raised several challenges caused by the use of both the wafer-bonding methodology and the unresolved need to match/transition among the three different lattice constants of the solar cell structure.

Thus, there remains a need in a semiconductor buffer (layer) that not only is configured to support a structural transition of the buffer material over a large range of lattice constant values, but that also is both electrically conductive and optically-transparent (to allow integration, on a chosen substrate, of materials with different lattice constants—those larger and those smaller than the lattice constant of the chosen substrate).

### SUMMARY

Embodiments of the invention provide solutions to problems that perpetuate in art related to design and fabrication of a multicomponent photonic device(s). In particular, embodiments of the invention solve the problem of structural defects caused by a sometimes-required wafer-bonding to form a multicomponent substrate for a photonic device. Implementations of the idea of the invention also address the problem of elevated optical absorption (and, therefore, attenuation) of broadband light in photonic structures, that is caused by the use of a buffer layer that is a) built with the use of multicomponent materials including two different group III elements and one group V element and that is b) configured to allow for only increase of the value of the lattice constant during the growth of such buffer layer.

In particular, in solving at least the above-identified problems, embodiments of the present invention provide an optically-transparent semiconductor metamorphic buffer layer characterized by a buffer layer lattice constant and judiciously configured (when grown on a first layer of material having a first lattice constant) to change the buffer layer lattice constant from a first value (that is substantially equal to the first lattice constant) to a second value (that is either greater than or smaller than the first value—that is, not equal to the first value). The metamorphic buffer layer is optically-transparent to light absorbed by the first layer and/or includes at least two elements from group V of the periodic table of elements. In any implementation, the metamorphic buffer layer can i) be configured to have upper and lower surfaces, and/or ii) be structured to define a plurality of sub-layers throughout the buffer layer in a direction transverse to the buffer layer, and/or iii) be characterized by a cut-off wavelength of absorption that reaches a minimum value in a sub-layer (of the plurality of the sublayers) that is spatially separated from each of the upper and lower surfaces. In a specific implementation, the optically-transparent metamorphic buffer layer includes at least one of AlPSb, GaPSb, AlAsSb, GaAsSb, and AlGaPAsSb. In substantially any embodiment, the optically-transparent metamorphic buffer layer can be configured a) to have a plurality of sub-layers defining at least one digital alloy and b) to have at least two elements from group V of the periodic table of elements, and/or c) satisfy one of the following conditions:
when a first sub-layer from the plurality has a first average composition and a first thickness and a second sub-layer from the plurality has a second average composition and a second thickness, a difference between the first and second average compositions is caused only by a difference between the first and second thicknesses;
when a first sub-layer from the plurality has a first average composition and a first material composition and a second sub-layer from the plurality has a second average composition and a second material composition, a difference between the first and second average compositions is caused only by a difference between the first and second material compositions; and
when a first sub-layer from the plurality has a first average composition, a first thickness, and a first material composition, and a second sub-layer from the plurality has a second average composition, a second thickness, and a second material compositions, a difference between the first and second average compositions is caused by both a) a difference between the first and second thicknesses and b) a difference between the first and second material compositions.

Embodiments of the invention additionally provide a semiconductor structure that comprises (i) an optically-transparent metamorphic buffer layer; (ii) a first light-absorbing layer underlying such metamorphic buffer layer and having a first bandgap and first absorption characterized by a first absorption spectrum; (ii) a second light-absorbing layer carried by the metamorphic buffer layer and having a second bandgap and second absorption characterized by a second absorption spectrum. Here, the metamorphic buffer layer is transparent to light that is absorbed by at least one of the first and second light-absorbing regions. In one particular implementation, the metamorphic buffer layer of the semiconductor structure is transparent to first light that is absorbed by the first light-absorbing region and to second light that is absorbed by the second light-absorbing region. Alternatively or in addition, the semiconductor structure may comprise a third light-absorbing layer disposed to be separated from the metamorphic buffer layer by either the first light-absorbing layer or the second light-absorbing layer (in this case, the metamorphic buffer layer is configured to be transparent to first light, second light, and third light, where the first light is light absorbed by the first light-absorbing layer, the second light is light absorbed by the second light-absorbing layer, and the third light is light absorbed by the third light-absorbing layer. In any of the above cases, however, the semiconductor structure may be configured to have upper and lower surfaces with a plurality of sublayers between the upper and lower surfaces, while different sublayers are characterized by different contents of at least one of the at least two elements from group V of the periodic table of elements.

In substantially any implementation of the semiconductor structure, the optically-transparent metamorphic buffer layer of the semiconductor structure may include i) at least one of AlPSb, GaPSb, AlAsSb, GaAsSb, and AlGaPAsSb, and/or ii) at least two elements from group V of the periodic table of elements. In any implementation, the optically-transparent metamorphic buffer layer may be judiciously configured, when grown on the first layer of material, to change a value of the metamorphic buffer layer lattice constant from the first value to a second value (here, the first value is substantially equal to the lattice constant of the first light-absorbing material layer and the second value is not equal to the first value). In a specific case, a layer immediately-adjacent to the optically-transparent metamorphic buffer layer and forming an interface with the optically-transparent metamorphic buffer layer is at least one of the first light-absorbing material layer, the second light-absorbing material layer, and an auxiliary buffer layer. (The auxiliary buffer layer may be disposed to form an interface with one of the first and second light-absorbing material layers.) In one implementation, the embodiment of the semiconductor structure is devoid of (that is, lacks or does not include) layers that are bonded to one another. Alternatively or in addition—and in substantially any embodiment, the semiconductor structure may a doped material layer that is immediately neighboring (adjacent to) the optically-transparent metamorphic layer (which, in turn, can also be configured as a doped layer, in a specific case). (When such structure is formed with the use of two doped material layers, one of the two conditions may be observed: a) the first doped material layer may contain a dopant of an n-type while the second doped material layer contains a dopant of the p-type, orb) the first doped material layer may contain a dopant of a p-type while the second doped material layer contains a dopant of the n-type.) In at least one of the above-identified embodiments, the optically-transparent metamorphic buffer layer may be doped with a dopant of the same type as a type of a dopant contained in a doped material layer that is immediately adjacent to the optically-transparent metamorphic buffer layer. Alternatively or in addition, in at least one of the above-identified embodiments, the optically-transparent metamorphic buffer layer may be structured to contain a plurality of layers where adjacent layers have at least one of different material compositions and different thicknesses.

Embodiments of the invention additionally provide an optical detector that includes an embodiment the semiconductor structure from the embodiments defined above (and, in a specific implementation—a multicolor optical detector, that is a detector configured to register optical signals at multiple wavelengths) and/or a solar cell that includes a semiconductor structure discussed above.

### BRIEF DESCRIPTION OF THE DRAWINGS

The following Description is made in reference to the Drawings that are used for illustration of but examples of implementations of the idea of the invention, are generally not to scale, and are not intended to limit the scope of the present disclosure.

FIG. 1 shows a cross-section of a device with buffer.

FIG. 2 is a schematic of a cross-section of a buffer layer.

FIG. 3 is cross section for digital alloy buffer.

FIG. 4 shows a schematic cross-section of a multicolor IR detector.

FIG. 5 shows a schematic cross section of a multicolor IR detector having an inverted growth stack.

FIG. 6 shows a schematic cross-section of a four-junction solar cell with a GaSb subcell according to the invention.

FIG. 7 shows a schematic cross-section of a four-junction solar cell with a GaSb subcell and an inverted growth stack according to the invention.

FIG. 8 is a more detailed cross-sectional scheme showing the layer structure of the device of FIG. 6.

FIG. 9 is a schematic cross-sectional view of a buffer layer transitioning lattice constant between the lattice constant of a GaSb substrate and the lattice constant of a GaAs substrate.

FIG. 10 is a schematic illustrating a two-color detector showing various electronic layers.

FIGS. 11A, 11B, 11C, and 11D schematically show lattice constant variation as various functions of thickness tin the growth direction for the metamorphic buffer.

Generally, the sizes and relative scales of elements in Drawings may be set to be different from actual ones to appropriately facilitate simplicity, clarity, and understanding of the Drawings. For the same reason, not all elements present in one Drawing may necessarily be shown in another.

### DETAILED DESCRIPTION

The following detailed description refers to the accompanying drawings that show, by way of non-limiting examples and illustrations, specific details and embodiments of the invention. These non-limiting examples are described in detail sufficient to enable those skilled in the art to practice the invention. Other embodiments, of course, may be utilized, and structural, logical, and electrical changes may be made without departing from the scope of the invention. Various embodiments discussed below are not necessarily mutually exclusive and are often related, and sometimes can be appropriately combined.

The numerical ranges and parameters listed in the description may represent specific values or be numerical approximations, and in the case of practical implementation of a specific embodiment may be deviated from based typical variations specific to respective testing measurements, as known in the art.

In particular, any numerical range recited herein is intended to include all sub-ranges encompassed therein and are inclusive of the range limits. For example, a range of “1 to 10” is intended to include all sub-ranges between (and including) the recited minimum value of about 1 and the recited maximum value of about 10, that is, having a minimum value equal to or greater than about 1 and a maximum value of equal to or less than about 10.

The use of “or” means “and/or” unless specifically stated otherwise, even though “and/or” may be explicitly used in certain instances.

The term “lattice-matched”, or similar terms, refer to semiconductor layers for which the in-plane lattice constants of the materials forming the adjoining layers materials (considered in their fully relaxed states) differ by less than 0.6% when the layers are present in thicknesses greater than 100 nm. Further, in devices such as multijunction solar cells with multiple layers forming individual junctions, junctions that are substantially lattice-matched to each other means define the situation when all materials in the junctions, that are present in thicknesses greater than 100 nm and considered in their fully-relaxed stated, have in-plane lattice constants that differ by less than 0.6%. Alternatively, the term substantially lattice-matched may refer to the presence of strain, as would be understood from context of the discussion. As such, base material layers, of a given layered structure, can have strain from 0.1% to 6%, from 0.1% to 5%, from 0.1% to 4%, from 0.1 to 3%, from 0.1% to 2%, or from 0.1% to 1%; or can have strain less than 6%, less than 5%, less than 4%, less than 3%, less than 2%, or less than 1%. The term “strain” generally refers to compressive strain and/or to tensile strain.

Conventionally, the term “metamorphic” refers to one pertaining to or characterized by change of form. The term “pseudomorphically-strained”, as used herein to refer to material layers, implies that layers made of different materials with a lattice-parameter difference can be grown on top of other lattice-matched or lattice-strained layers without generating misfit dislocations. In certain embodiments, the lattice parameters of pseudomorphically-strained layers differ by up to +/−3.5%. In related embodiments, the lattice parameters differ by up to +/−2%. In other embodiments, the lattice parameters differ by up to +/−1%, by up to +/−0.5%, or by up to +/−0.2%.

The idea of the invention stems from the realization that fabrication of a practically-functional multiwavelength photonic devices (such as, for example, optical detectors configured to operate across a broadband spectral range that is uncharacteristically large for the existing detector) can be achieved without the use of a wafer-bonding proceed but by utilizing an optically-transparent transitional buffer layer to operably connect multiple spectrally-absorbing regions of the device both optically and structurally.

Implementations or embodiments of the idea of the invention address a combination of problems persisting with the use of known combinations of currently-employed in industry metamorphic buffer layers. Specifically, at least two types of problems are addressed: (i) the problem of structural defects caused by a sometimes-required wafer-bonding to form a multicomponent substrate for a photonic device, and (ii) the problem of optical absorption (and, therefore, attenuation) of broadband light in photonic structures, caused by the use of a buffer layer that is built with the use of multicomponent materials including two different group III elements and one group V element and that is configured to allow for only increase of the value of the lattice constant during the growth of such buffer layer. At least these problems are addressed by devising a metamorphic layer

(i) that includes at least two group-V elements,

(ii) that is configured such that, when being deposited on an underlying chosen substrate as a buffer layer, is characterized by increase of the lattice constant (as function of thickness of the layer) or, alternatively, is characterized by decrease of the lattice constant (as a function of thickness); and

(iii) that remains substantially optically-transmitting throughout the thickness of the layer for at least one wavelength from a broadband range of wavelengths chosen for the operation of a photonic device utilizing such a buffer layer. In other words, implementations of the buffer layer structured according to the idea of the invention allow for a bi-directional change of lattice constant throughout the thickness of the optically-transparent buffer layer containing at least two material from group V of the periodic table.

In particular, the methodologies of the present invention facilitate a cost-efficient process of manufacture of high-quality semiconductor devices including multijunction solar cells and optical detectors of broadband (multicolor) light (referred to, interchangeably, as “multicolor detectors”). The disclosure illustrates photonic devices containing optically-transparent metamorphic semiconductor buffer layer(s) that transition(s) lattice constant from a first lattice constant value to a second lattice constant value, a first optical absorption region having the first lattice constant value and a first absorption spectrum, and a second optical absorption region having the second lattice constant and a second absorption spectrum. The term “solar cell” (which may be interchangeably used herein with the term “photovoltaic cell”) refers to and defines an electrical device that is configured to convert the energy of light directly into electricity via the photovoltaic effect.

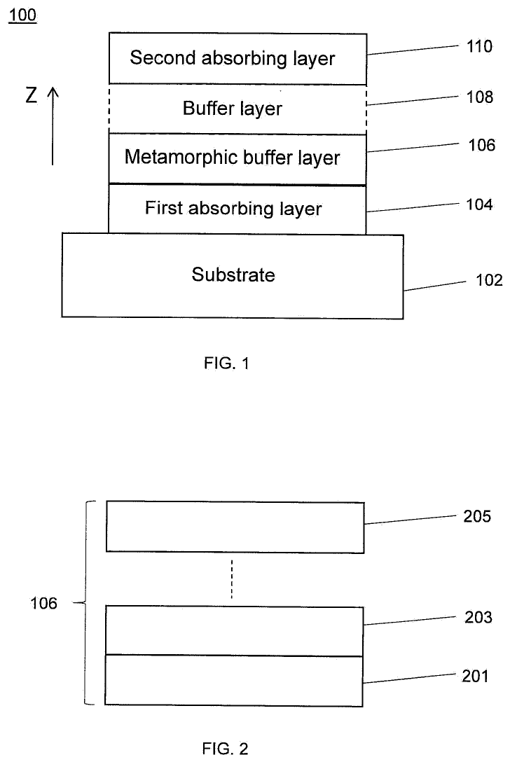

FIG. 1 is a sectional view of an example of a specific semiconductor optoelectronic device 100, structured according to the idea of the invention. The embodiment 100 includes a substrate 102, a first absorbing layer 104, a metamorphic buffer layer 106, an optional buffer layer 108, and a second absorbing layer 110. (While, for simplicity, each layer is shown as a single layer, it is understood that each layer can include or carry one or more layers with differing compositions, thicknesses, and doping levels to provide desired optical and/or electrical functionality, and to improve quality of material interface(s), electron transport, hole transport and/or other optoelectronic properties.) In general, and unless explicitly stated otherwise, as broadly used and described herein, the reference to a layer as being “carried” on a surface of an element or another layer refers to both a layer that is disposed directly on the surface of the element/layer or a layer that is disposed on yet another coating, layer or layers that are disposed directly on the surface of the element/layer.

Substrate 102 is characterized by (or has) a first (value of) lattice constant. Depending on the specifics of a particular implementation, the substrate 102 can include gallium antimonide (GaSb), indium arsenide (InAs), indium phosphide (InP), gallium arsenide (GaAs), silicon (Si), germanium (Ge), or an epitaxially grown material (such as a ternary or quaternary semiconductor). The first lattice constant of substrate 102 is judiciously chosen to minimize defects in materials subsequently grown on the substrate 102. The thickness of the substrate 102 can be defined within a large range of values between about 50 μm and up to about 1 mm in thickness, such as between about 250 μm and 700 μm. In some embodiments, substrate thinning may be used to produce a semiconductor device, with a final substrate thickness less than 150 μm. In some embodiments, after growth of the semiconductor layers on substrate 102, the substrate itself may be optionally thinned or even removed using a substrate removal process. Substrate 102 can be a composite substrate in that it may include more than one vertically (along the z-axis as shown in FIG. 1) stacked material layer and may also be optically-absorbing within the range of wavelengths of interest. Substrate 102 can be a doped substrate (such as a p-doped substrate or an n-doped substrate), or, in a related embodiment, it may be a semi-(electrically-)insulating (SI) substrate. A first absorbing layer 104 overlies or is positioned on or is carried by the substrate 102. In one specific case, the first absorbing layer 104 is configured to be lattice-matched or pseudomorphically strained with respect to the substrate 102 and includes a suitable III-V compound semiconductor. The first absorbing layer 104 has a first bandgap and absorbs light over a first wavelength range. In a specific case, the substrate 102 can be optically absorbing and/or contain a first absorbing region.

The metamorphic buffer layer 106 overlies or is positioned on or is carried by the first absorbing layer 104 on the one hand, and is in turn overlaid with or carries the following layer (either the optional buffer layer 108 or the second absorbing layer 110, as shown in FIG. 1).

Accordingly, the metamorphic buffer layer 106 is judiciously configured to provide a structural transition of a material lattice constant value between the first value of the lattice constant (of the first absorbing layer 104 at the interface with the metamorphic buffer layer 106) and the second value of lattice constant (of the following layer 108 or 110 at the interface with the metamorphic buffer layer 106) regardless of whether such structural transition (effectuated as a result of the growth of the metamorphic buffer layer 106 in the growth direction z, away from the substrate 102) increases or decreases the lattice constant.

The purpose of the so-formed lattice constant transition is to gain the ability to subsequently (during the sequential growth of the structure 100 in the growth direction z) to overlay semiconductor layer(s) (that are lattice-matched or pseudomorphically strained to the second lattice constant—in this case, either the optional buffer layer 108 or the second absorbing layer 110) on top of the metamorphic buffer layer 106. The metamorphic buffer layer 106 is also configured to be optically-transparent to light that in not absorbed upon propagation towards the layer 106 through either the bottom portion of the structure (in this example, the substrate 102 and/or the layer 104) or the top portions of the structure 100 such as layer(s) 108/110), or through both the top and bottoms portions of the structure 100. As a result of being so configured, the metamorphic buffer 106 allows for the light that has transmitted through the combination of the layer(s) (110, 108) and that can be absorbed by the layer 104 to be absorbed by the layer 104. Alternatively or in addition, the buffer 106 allows for the light that has transmitted through the combination of the layer(s) (102, 104, 108) and that can be absorbed by the layer 110 to be absorbed by the layer 110. The metamorphic buffer 106 can include more than one material layer, but is illustrated as including a single layer in an embodiment for simplicity of the illustration. Metamorphic buffer layer 106 can comprise any suitable III-V compound semiconductor material, as described herein.

Buffer layer 108 can be optionally included in semiconductor device 100, overlying metamorphic buffer layer 106. Buffer layer 108 can be included in the structure 100, for example, to provide a smooth growth surface for subsequent deposition of overlying semiconductor materials, and can comprise any suitable III-V compound semiconductor. In an embodiment where this buffer layer 108 is present, the buffer layer 108 has the second value of the lattice constant.

The second absorbing layer 110 overlies or is positioned on or is carried by the metamorphic buffer layer 106. The second absorbing layer 110 can be lattice-matched or pseudomorphically-strained with respect to the second value of the lattice constant provided by the (upper as shown) interface of the metamorphic buffer 106, and can contain any suitable III-V compound semiconductor. The second absorbing region 110 has a second bandgap and absorbs light over a second wavelength range.

It is appreciated by a skilled person that additional structural and/or functional layers (not shown) such as contacting layers, conductive layers, and tunnel junctions, to name just a few, can also be formed to complete a device with fully-enabled optical and electrical functionality.

FIG. 2 illustrates a cross-section of an embodiment of the metamorphic buffer layer 106. As shown, the buffer layer 106 includes at least two sub-regions or sub-layer with different respectively-corresponding average material compositions and different respectively-corresponding lattice constants. In the embodiment shown, the buffer 106 contains multiple sub-regions/sub-layers with different average alloy compositions and different lattice constants. Sub-region 201 has a first composition and a first lattice constant, sub-region 203 has a second composition and a second lattice constant, and sub-region 205 has a third composition and a third lattice constant. The compositions for the sub-regions are judiciously chosen such that the lattice constant of each particular sub-region monotonically changes (necessarily in the same single direction, for example along the growth axis z) between the lattice constant of an underlying semiconductor sub-region (for example, GaSb or GaAs) and that of an overlying semiconductor sub-region (for example, GaAs or GaSb). In a non-limiting example, the lattice constant difference between two adjacent sub-regions of metamorphic buffer (such as, for example, sub-regions 201 and 203) is less than 0.5%. In other examples, such difference is less than 0.75%, or less than 1%, or less than 2%. In some other embodiments, the lattice constant difference between adjacent regions of the metamorphic buffer is less than 4%. The thickness of each sub-region or sub-layer of the metamorphic buffer is typically such that misfit dislocations can occur. As will be explained further, the metamorphic buffer is designed as a dislocation filter configured to spatially confine the dislocations at the metamorphic buffer layer itself, and preventing the propagation of the misfit dislocations into subsequent epitaxially-grown layers.

In one embodiment, the metamorphic buffer layer 106 includes at least one group III element (such as Al or Ga) and at least one group V element (such as Sb). In a related embodiment, the metamorphic buffer layer 106 includes at least two group V elements (such as P and Sb, or As and Sb, for example). According to the idea of the invention, the presence of Sb in the metamorphic buffer allows a formation of the metamorphic buffer layer with a lattice constant that is approximately equal to a large lattice constant of one material (conventionally-used as a substrate material) such as GaSb or InAs, while the presence of a second group V element is judiciously chosen to achieve a lattice constant approximately equal to a small lattice constant of another material (also conventionally-used as a substrate material) such as GaAs, Ge or Si.

Notably, in various implementations the metamorphic buffer layer 106 generally includes AlPSb, and/or GaPSb, and/or AlGaPSb, and/or AlAsSb, and/or GaAsSb, and/or AlGaAsSb.

### Example 1 (the Use of AlPₓSb₁₋ₓ)

A non-limiting example of a specific metamorphic buffer layer structured around AlPₓSb₁₋ₓ and configured to provide a transition between the lattice constants of GaAs and GaSb is described in Table 1. In this and other examples, the value of “absorption edge” refers to and defines the wavelength corresponding to the spectral cut-off of the absorption of the semiconductor material (with light at wavelengths shorter than such cut-off wavelength being absorbed in this semiconductor material).

TABLE 1
Example of a metamorphic buffer layer

| Sub-region/ | | Lattice constant | Min bandgap | Absorption edge |
|---|---|---|---|---|
| Sub-layer | x | (Å) | (eV) | (nm) |
| 1 | 0.71 | 5.6584 | 1.64 | 755 |
| 2 | 0.61 | 5.7256 | 1.47 | 844 |
| 3 | 0.52 | 5.7861 | 1.36 | 913 |
| 4 | 0.43 | 5.8465 | 1.29 | 960 |
| 5 | 0.34 | 5.9070 | 1.27 | 976 |
| 6 | 0.25 | 5.9675 | 1.29 | 960 |
| 7 | 0.16 | 6.0289 | 1.36 | 914 |
| 8 | 0.06 | 6.0952 | 1.48 | 838 |

In one case, a material with the composition of AlP_{0.71}Sb_{0.29} is approximately lattice-matched to GaAs, and a material with the composition of AlP_{0.06}Sb_{0.94} is approximately lattice-matched to GaSb. The minimum bandgap for the metamorphic buffer layer of Table 1 varies between about 1.27 eV, and 1.64 eV, corresponding to a long-wavelength absorption edge between 755 nm and 960 nm. Light at wavelengths beyond about 960 nm should not suffer from any appreciable absorption in such metamorphic buffer layer. This layer, therefore, is practically and operationally fit to facilitate integration of multijunction cells employing absorptive materials (such as dilute nitrides with bandgaps between 0.7 eV and 1.2 eV) with GaSb substrates (when this layer is used as a metamorphic buffer layer). Similarly, multicolor detectors based on a combination of materials such as dilute nitrides and type-II Sb-based superlattices can be devised and fabricated with the use of such a metamorphic buffer.

The material composition of the metamorphic buffer layer of Example 1 quasi-monotonically decreases in terms of the fraction (content) of P, which in turn causes a quasi-monotonic increase of the lattice constant, as shown. This example demonstrates an embodiment of the metamorphic buffer layer of the invention the wavelength absorption edge of which is increasing with growth of the layer, reaching a maximum, and then decreasing towards the upper boundary of the metamorphic buffer layer. In this case, the metamorphic buffer layer is shown to include eight sub-regions of different average composition. The metamorphic buffer layer can be between about 0.5 μm and about 20 μm thick. The thickness of each sub-region of the metamorphic buffer can vary between about 50 nm and about 2 μm.

The metamorphic buffer layer can be doped as n-type, or doped as p-type or undoped, according to a specific application. For example, if the buffer is grown on an n-doped underlying layer, and the device application required that the buffer be electrically conductive, the buffer can be doped to be n-type. If the buffer is grown on a p-doped underlying layer, the buffer can be doped to be p-type. If electrical conductivity is not required through the buffer, it can be undoped. By stepping/incrementing the composition and lattice constant, the metamorphic buffer layer 106 is designed to provide a low defect density for subsequent epitaxial growth at the new lattice constant provided by the last layer of the buffer layer.

### Example 2 (the Use of GaPₓSb₁₋ₓ)

A non-limiting example of a specific metamorphic buffer layer structured around GaPₓSb₁₋ₓ and configured to provide a transition between the lattice constants of GaAs and GaSb is shown in Table 2.

TABLE 2
Example of a metamorphic buffer layer (using GaPSb)

| Sub-region/ | | Lattice constant | Min bandgap | Absorption edge |
|---|---|---|---|---|
| Sub-layer | x | (Å) | (eV) | (nm) |
| 1 | 0.68 | 5.6574 | 1.22 | 1020 |
| 2 | 0.57 | 5.7283 | 0.98 | 1265 |
| 3 | 0.46 | 5.7992 | 0.81 | 1529 |
| 4 | 0.34 | 5.8766 | 0.70 | 1770 |
| 5 | 0.22 | 5.9540 | 0.67 | 1857 |
| 6 | 0.11 | 6.0250 | 0.71 | 1756 |
| 7 | 0 | 6.0959 | 0.81 | 1531 |

In one case, a material with the composition of GalP_{0.68}Sb_{0.29} is approximately lattice-matched to GaAs, and a material with the composition of GaSb₀ is lattice-matched to GaSb. The minimum bandgap for the metamorphic buffer layer of Table 2 varies between about 0.67 eV, and 1.22 eV, which corresponds to a long-wavelength absorption edge between 1020 nm and 1860 nm. Light at wavelengths beyond about 1860 nm should not experience any appreciable absorption upon propagation through or in such metamorphic buffer layer. This layer, therefore, is practically and operationally fit to facilitate integration of multicolor photodetectors employing absorptive materials (such as dilute nitrides with bandgaps between 0.7 eV and 1.2 eV) and materials with bandgaps smaller than about 0.65 eV, such as type-II Sb-based superlattices lattice-matched to GaSb substrates (when this layer is used as a metamorphic buffer layer). In one implementation, the buffer thicknesses and doping levels can be chosen according to the ranges provided in Example 1.

### Example 3 (the Use of AlAsₓSb₁₋ₓ)

A non-limiting example of a specific metamorphic buffer layer structured around AlAsₓSb₁₋ₓ and configured to provide a transition between the lattice constants of GaSb and GaAs is presented in Table 3.

TABLE 3
Example of a metamorphic buffer layer (using AlAsSb)

| Sub-region/ | | Lattice constant | Min bandgap | Absorption edge |
|---|---|---|---|---|
| Sub-layer | x | (Å) | (eV) | (nm) |
| 1 | 0 | 6.1355 | 1.58 | 785 |
| 2 | 0.2 | 6.0404 | 1.65 | 752 |
| 3 | 0.4 | 5.9453 | 1.74 | 713 |
| 4 | 0.6 | 5.8502 | 1.86 | 667 |
| 5 | 0.8 | 5.7551 | 1.99 | 623 |
| 6 | 1 | 5.66 | 2.15 | 577 |

In one case, a material with the composition of AlSb is approximately lattice-matched to GaSb, and a material with the composition of AlAs is approximately lattice-matched to GaAs. The minimum bandgap for the metamorphic buffer layer of Table 3 varies between about 1.58 eV, and 2.15 eV, which corresponds to a long-wavelength absorption edge respectively located between 785 nm and 577 nm. Light at wavelengths beyond about 785 nm should not experience any appreciable absorption upon propagation through or in such metamorphic buffer layer. This layer, therefore, is practically and operationally fit to facilitate integration of multijunction cells employing absorptive materials (such as dilute nitrides with bandgaps between 0.7 eV and 1.2 eV) with GaSb substrates (when this layer is used as a metamorphic buffer layer). Similarly, multicolor detectors based on a combination of materials such as dilute nitrides and type-II Sb-based superlattices can be devised and fabricated with the use of such a metamorphic buffer. In one implementation, the buffer thicknesses and doping levels can be chosen according to the ranges provided in Example 1.

It is appreciated that, in general, a specific implementation of the metamorphic buffer layer may include the use of any combination of the materials of interest—for example, a combination of the materials use for buffer layers of Examples 1, 2, and 3.

### Example 4 (Continuously Graded AlGaAsSb)

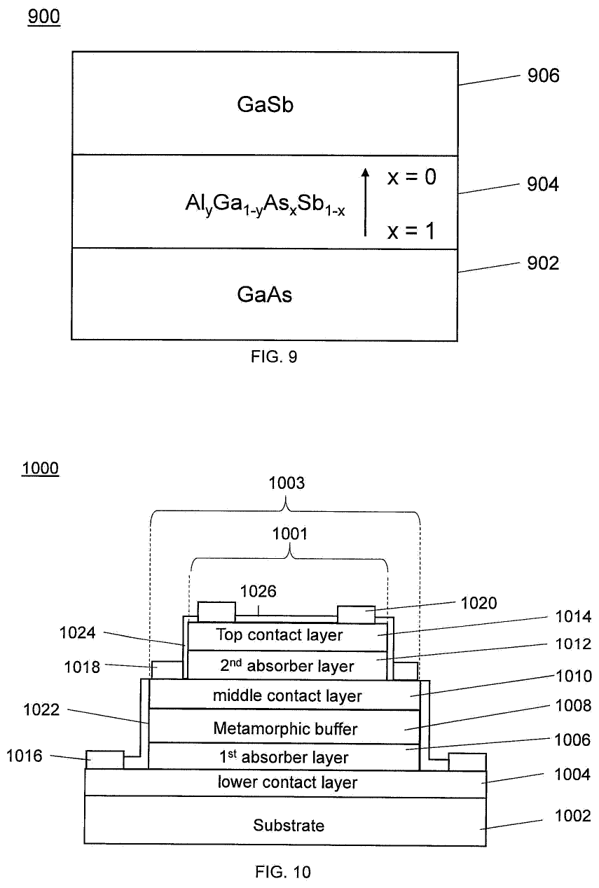

A non-limiting example of a material stack containing a specific optically-transparent metamorphic buffer layer structured around Al_{y}Ga_{1-y}AsₓSb₁₋ₓ (with 0≤y≤1, and 0≤x≤1, and configured to provide a structural transition between the lattice constants of GaAs and GaSb) is shown in FIG. 9. Structure 900 comprises a GaAs substrate 902, a graded Al_{y}Ga_{1-y}AsₓSb₁₋ₓ (0≤x≤1) buffer 904 overlying the GaAs substrate, and III-V compound semiconductor layer(s) (including GaSb) 906 overlying the buffer 904. The As-fraction x of the graded Al_{y}Ga_{1-y}AsₓSb₁₋ₓ layer 904 varies from 1 to 0 through its thickness (along the growth direction or axis, illustrated with an arrow). At the interface with the GaAs substrate 902, the material fraction of As in the buffer layer 904 is x=1 and the graded Al_{y}Ga_{1-y}AsₓSb₁₋ₓ layer 904 substantially only contains As as the group V element. At the opposite interface (the one formed by the layer 904 with the III-V layer(s) 906), x=0 and the graded Al_{y}Ga_{1-y}AsₓSb₁₋ₓ layer 904 substantially only contains Sb as the group V element. Therefore, the graded Al_{y}Ga_{1-y}AsₓSb₁₋ₓ layer 904 provides a transition, throughout its thickness along the growth direction, in a lattice parameter from that of the GaAs substrate (5.6533 Å) to that of GaSb (6.0959 Å). It is important to note that for this specific metamorphic buffer layer, only the group V material composition needs to be varied. In one specific implementation, the group III composition may remain fixed (that is, the value of “y” in the composition of Al_{y}Ga_{1-y}AsₓSb₁₋ₓ may be maintained constant throughout the thickness of the buffer 904), or, in a related implementation, it can be varied (0≤y≤1): since the lattice constants of AlAs and GaAs are approximately equal and the lattice constants of AlSb and GaSb are approximately equal, the variation of the lattice constant variation throughout the thickness of the buffer depends primarily on the group V composition of the buffer material. The metamorphic buffer layer can be dimensioned to have thickness between about 0.5 μm and about 20 μm. Depending on a specific implementation and/or application, the metamorphic buffer layer can be doped as n-type, or doped as p-type or undoped. By grading the composition and/or value of the lattice constant along the growth axis, the metamorphic buffer layer 106 is designed to provide a low defect density for subsequent epitaxial growth at the new lattice constant provided by the last layer of the buffer layer.

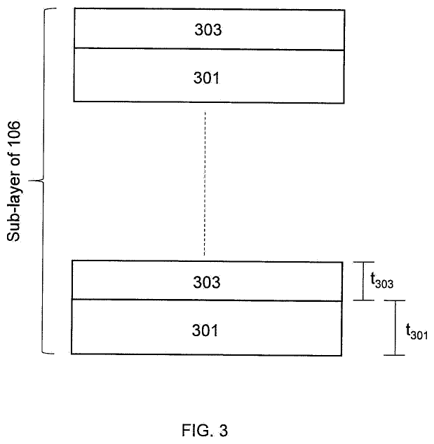

Examples of Sub-Layer Structures. In another embodiment, shown in FIG. 3, a single sub-region or sub-layer of the metamorphic buffer layer 106 is shown (such as a sub-layer 201 of FIG. 2), which includes a digital alloy (hereinafter referred to as “DA”). As understood by those skilled in the art, a digital alloy is an alloy grown with an average composition that includes two or more different semiconductor components having different compositions. The average composition of the digital alloy depends on the thickness and composition of each of the constituent layer types used to form the superlattice. The superlattice layers (shown as 301, 303) are typically thin, of the order of 10-100 Angstrom (1-10 nm), so that the resulting overall material has the properties of that having the average composition and not of the individual layers constituting the alloy. Considering the small thickness values, many DA layers are therefore required to produce the buffer layer. In this example, the DA contains two semiconductor layers 301 and 303 with thicknesses t301 and t303, respectively, where the compositions of layer 301 and 303 are different. (The principle of formation of a sub-region of a metamorphic buffer can be expressed as follows: in a digital alloy, the composition and thickness of layer 301 and composition and thickness of 303 provide average composition. To provide differing average compositions, with different lattice constants, different thicknesses for layers 301, 303 could be used.) Adjacent regions/layers of the metamorphic buffer layer can be grown in this fashion, varying the average composition of the layer by adjusting the layer thicknesses and/or layer compositions. A DA superlattice can include more than two different layer types, wherein each layer type is periodically repeated in an operationally-controllable fashion (optionally—periodically, in a form of A/B/A/B . . . , or A/B/C/A/B/C . . . ) through a superlattice. However, only two layer types are illustrated in FIG. 3 for simplicity and ease of discussion.

Referring again to Example 1 of Table 1, for a given sub-region of the metamorphic buffer with a given average composition, superlattice layers comprise AlP_{y}Sb_{1-y} and AlP_{z}Sb_{1-z}, where the values of y and z are different and where the layer thicknesses are of the order of several nanometers or tens of nanometers. Growth of the metamorphic buffer as a DA structure, according to the idea of the invention, facilitates and enables a broad range of compositions to be formed (via the use of molecular beam epitaxy, or MBE, for example) by varying the growth time of the individual (sub-)layers only, while keeping the growth parameters for the different growth sources constant.

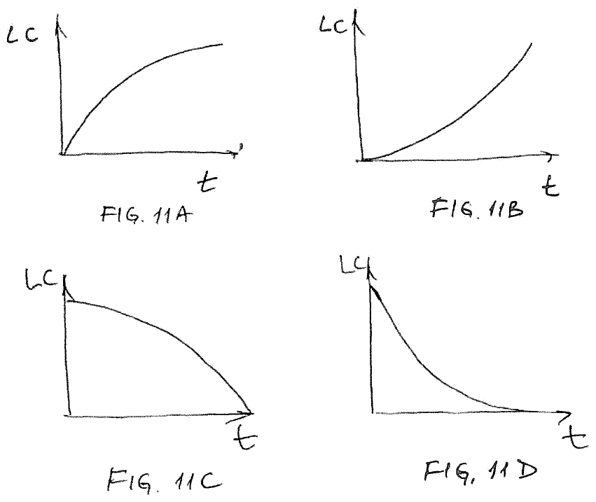

The structures shown in FIG. 2 and FIG. 3 can be described as step-graded metamorphic buffers. However, an embodiment of the invention may include other metamorphic designs, for example, those based on the composition of a metamorphic buffer that varies substantially continuously in the growth direction so that the lattice constant also varies continuously as a function of the growth thickness, as shown in Example 4 (FIG. 9). Generally, a variation of the material compositional within a single sub-layer (such as sub-layer 201) of the metamorphic buffer layer 106 (along the z-axis or growth direction, for example, as shown in FIG. 1) can be chosen to follow at least one of different dependencies such as linear, or nonlinear (parabolic or quadratic or generally convex; or generally concave). More than one spatially-graded compositional layer can be used. For the purposes of illustration only, schematics of functional dependencies showing the nonlinear variation (as a function of the thickness of the metamorphic buffer, t) of the lattice constant, LC, are shown in: FIG. 11A (a “concave” profile of the lattice constant increasing as a function of the thickness t in the growth direction z), FIG. 11B (a “convex” profile of the increasing lattice constant); FIG. 11C (a convex profile of the decreasing lattice constant), and FIG. 11D (a concave profile of the decreasing lattice constant).

According to the idea of the invention, the compositions, number of sub-layers, and their thicknesses for a given metamorphic buffer layer are selected to filter (limit the propagation of) dislocation defects and to achieve a smooth growth surface (at the termination of the metamorphic buffer layer) that is suitable for the subsequent epitaxial growth of additional layers to form the resulting device configured for a specific application. Relaxation of a semiconductor material, where the lattice constant of the material returns to its original lattice constant, as opposed to a desired lattice constant set by the adjacent semiconductor layers and/or substrate, can cause the formation of many defects, including threading dislocations. These defects can often propagate into the succeeding layers of the buffer and eventually into the active region of the device layers grown on the buffer. Threading dislocations are the main source of poor device performance in lattice-mismatched structures. However, strain within the buffer material (and possibly also bond strength between certain III-V atoms) can exert forces on these dislocations, causing a significant fraction of the dislocations to bend into planes transverse or even perpendicular to the growth direction. This causes a decrease in the number of threading dislocations propagating through the buffer layers (that is, along the direction of growth). Such process—a dislocation filtering—may be particularly effective in the case of large local strains such as those present near the abrupt interfaces (that is, interfaces defined by just a few—one or two, for example—material monolayers) between the different buffer layers in structures similar to those schematically depicted in FIG. 2 and FIG. 3. The combination of dislocation bending and dislocation annihilation (with the latter term referring to direct interference of one dislocation with another) can result in a lower defect density at the device interface sub-layer(s) of the metamorphic buffer (i.e., the sub-layer(s) of the metamorphic buffer that are immediately adjacent to the other device layers). Lower defect density provides a more attractive growth platform for the overlying semiconductor device.

Some semiconductor alloy compositions can exhibit poor electrical properties in doped materials as a result of a high ionization energy of a dopant in that particular composition, in comparison with other compositions of the semiconductor alloy that have lower ionization energies, thus facilitating doping of those material compositions. (For example, n-doping of AlGaAs is known to result in formation of highly doped materials in case of Al molar fraction (or content) of up to about 30% and above about 70%. For Al composition between 30-70%, however, activation energies are high and so adding dopants into the material at these Al concentrations, these dopants remain substantially electrically inactive.) Accordingly, if the metamorphic buffer layer 106 (or a given sub-region of the metamorphic buffer layer) is grown as a bulk (random) alloy of an average composition, a situation may occur when a poor carrier concentration (and hence inferior electrical properties) result for certain compositions of the constituents of such metamorphic buffer layer. Using an example of the DA structure (FIG. 3), the average composition of metamorphic buffer layer 106 is determined by the compositions and the thicknesses of the superlattice layers 301 and 303. The composition of the layers 301 and 303 can be chosen such that at least one of the layer 301 and 303 includes a highly-doped semiconductor material with a conductivity type (i.e. n-type or p-type) chosen to provide a lateral contact and current spreading in the overall, finally fabricated device.

In the case where both layer 301 and layer 303 include a highly-doped semiconductor material, a higher vertical current flow (along the z-axis) in the resulting device that includes these layers may also be achieved as compared to is the case when the metamorphic buffer is structured as a bulk (random) alloy. In the case where only one of the layer 301 and layer 303 includes a highly-doped semiconductor material, the thickness of the layer doped at a lower level is chosen to be sufficiently thin (for example, less than 2 nm in thickness) so as to allow coupling or tunneling of carriers from the highly doped layers, thereby permitting a higher vertical current flow than can be achieved in operation—as compared to the case of using a bulk (random) alloy.

It will be understood that the doping of different layers of a superlattice may be chosen to be different, so that a vertical current flow and a lateral current flow (that is a flow of current in a direction transverse to the direction of growth of the semiconductor structure) may be varied throughout the metamorphic buffer layer 106 in order to provide a desired overall current flow. In one embodiment, by way of example, a configuration may include a region with a high lateral current flow (relative to a vertical current flow) in a region of the buffer layer 106 and a high vertical current flow in another region of buffer layer 106. (As a possible example, such structure may include a superlattice layer sandwiched between two electrically-insulating layers.) Further, layers of the superlattice may be pseudomorphically (or coherently) strained, which may also yield higher mobilities than for bulk semiconductor.

The metamorphic buffer layers, and other layers required in devices, can be formed using semiconductor deposition techniques including molecular beam epitaxy (MBE), and chemical vapor deposition (CVD). Growth temperatures can be between about 350 C and 600 C, and the ration of the different group V materials and the different group III materials (the VIII ratio) arriving at the surface can be between 1 and 100.

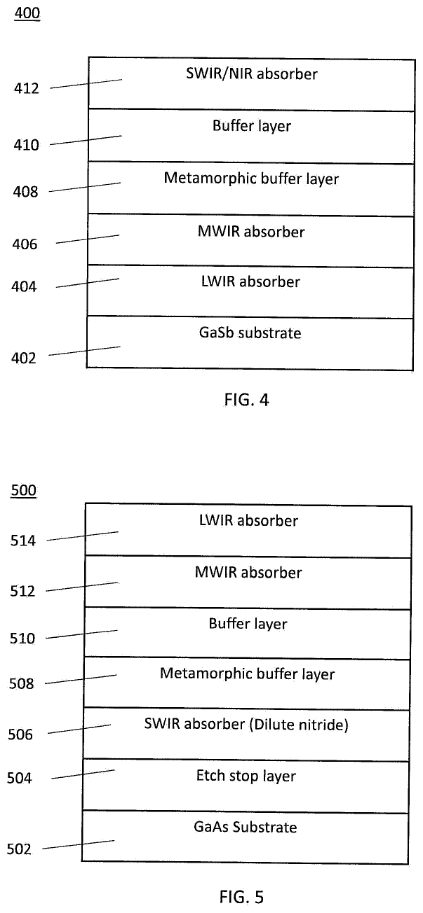

Examples of Device Structures. FIG. 4 illustrates a cross-section of a material structure of a multicolor detector formed on a GaSb substrate 402 (the GaSb structure having a first lattice constant). A long wavelength infrared (LWIR) absorption region 404 is formed on substrate 402. A mid wavelength infrared (MWIR) absorption region 406 is then formed on the LWIR absorber 404. LWIR layer 404 and MWIR layer 406 can be fabricated by employing InAs/GaSb type-II strained superlattice structures. The MWIR layer 406 is configured to absorb light at wavelengths in the approximately 3 micron to 5 micron range, and the LWIR layer is structured to absorb light at wavelengths at least in the range from approximately 8 microns to approximately 10 microns. (Examples of strained layer superlattices and LWIR and MWIR absorber layers are described by D. L. Smith et al., in “Proposal for strained type II superlattice infrared detectors”, J. Appl. Phys. 62, 2545 1987; by H. Kroemer, in “The 6.1 Å family (InAs, GaSb, AlSb) and its heterostructures: a selective review”, Physica E 20, pp196-203, 2004; by E. A. Plis in “InAs/GaSb Type-II Superlattice Detectors”, Advances in Electronics, Article ID 246769 2014; by M. Razeghi et al., in “Recent Advances in LWIR Type-II InAs/GaSb Superlattice Photodetectors and Focal Plane Arrays at the Center for Quantum Devices”, Proc. IEEE Vol. 97, No. 6, pp 1056-1066, 2009; and by E. H. Eifer et al., in “W-Structured type-II superlattice based long and very-long wavelength infrared photodiodes”, Proc. SPIE Vol. 5732, pp 259-272, 2005; each of which is incorporated by reference herein.

A metamorphic buffer layer 408 is formed on the MWIR absorber 406. In one embodiment, the metamorphic buffer 408 includes AlPSb, However, the buffer 408 can contain GaPSb, AlGaPSb, AlAsSb, GaAsSb and/or AlGaAsSb. The metamorphic buffer layer is optically-transparent to light at wavelengths that are absorbed by LWIR absorber 404 and MWIR absorber 406. When grown, the metamorphic buffer layer 408 is structured to transition the lattice constant from that of GaSb to a second (smaller) lattice constant, as discussed above. In the example shown in FIG. 4, the metamorphic buffer 408 transitions a first lattice constant to the value approximately equal to that of GaAs. An optional buffer layer 410 can then be formed above the metamorphic buffer 408. The buffer layer 410 can comprise GaAs and/or (InGaAs). Finally, a short-wavelength infrared or near-infrared wavelength absorber layer 412 is formed. The absorber layer 412 can include materials such as GaAs, InGaAs or a dilute nitride material such as GaInNAs, GaInNAsSb, GaNAsSb, or GaInNAsBi. The absorber layer 412 is lattice-matched or pseudomorphically-strained to the second lattice constant. Absorber layer 412 is configured to absorb light at wavelengths shorter than about 2 microns. For example, the absorber layer 412 can comprise Ga₁₋ₓInₓN_{y}As_{1-y-z}Sb_{z}, where x, y and z can be 0≤x<0.4, 0<y≤0.10 and 0<z≤0.20, respectively. X, y and z values can be defined as 0.01≤x≤0.4, 0.02≤y≤0.10 and 0.001≤z≤0.20, respectively. (See also the description of sub-ranges below.) Absorber layer 412 can have a bandgap within a range from 0.7 eV and 1.1 eV (such that the absorber (or active) layer is enabled to absorb or emit light at wavelengths up to 1.8 μm). In some embodiments, bismuth (Bi) may be added to the absorber layer 412 as a surfactant during the growth of the dilute nitride material, to improve material quality (for example, to reduce the defect density) and the device performance. Additional layers are typically required to form a complete optically and electrically functional device but are not shown for simplicity of illustration. These layers can include contacting layers, current spreading layers, barrier layers and the like.

FIG. 5 shows an example of a cross-section of a multicolor detector formed on a GaAs substrate with the use an “inverted” growth process. Here, the shortest-wavelength absorption region is grown before the longest-wavelength absorption region is grown. In this embodiment, an etch stop layer 504 is formed on the GaAs substrate 502. The etch stop layer 504 includes a layer that has a high etch selectivity with respect to the substrate 502 and the overlying epitaxial layers. Examples of etch stop layers with a high etch selectivity to GaAs include InGaP and AlInP. The short-wave absorber 506 is formed on etch stop layer 504. The short wave absorber 506 comprises an initial contact layer of GaAs or InGaAs, and an absorbing layer (such as GaAs, InGaAs) and/or a dilute nitride such as GaInNAsSb, as described in the preceding example. A metamorphic buffer layer 508 is then grown on the SWIR absorber 506 as a layer transparent to light that is absorbed by the SWIR absorber 506. In one embodiment, the metamorphic buffer 508 comprises AlPSb, In a related implementation(s), it can comprise GaPSb, AlGaPSb, AlAsSb, GaAsSb and/or AlGaAsSb. According to the idea of the invention, the metamorphic buffer layer 508 is optically-transparent to light that is absorbed by the overlying MWIR absorber 512 layer and/or LWIR absorber layer 514.

Furthermore, the metamorphic buffer layer 508 is judiciously structured, as described above to transition the value of the lattice constant from that of GaAs to a second (larger in value) lattice constant. In the example shown, the lattice constant of the metamorphic buffer 508 is chosen to be varied, during the process of growth of the buffer 508, to a lattice constant approximately equal to that of GaSb. An optional buffer layer 510 is then formed. The buffer layer 510 can be, for example, GaSb or AlSb. The MWIR absorber layer 512 is then formed. (Notably, the structured grown thus far can be used as a material basis for a two-color optical detector). The LWIR absorber 514 is then further fabricated to provide a base structure for a three-color optical detector. The designs and compositions of the layer(s) 512 and/or 514 may be those described in the preceding example.

After the growth of all layers is accomplished, the overall structure can be bonded, using an adhesive to another carrier or substrate. The GaAs substrate 502 and the etch stop layer 504 can then be removed with the use of a sequence of known lapping and/or etching steps. (A comprehensive review and list of wet etchants and their selectivity is provided by Clawson in “Guide to references on III-V semiconductor chemical etching”, Mat. Sci. Eng. 31, pp1-438, 2001; and is incorporated herein by reference).

FIG. 10 is a simplified cross-sectional view of a two-color detector 1000. A lower contact layer 1004 is formed on a substrate 1002 and includes a III-V compound semiconductor material (in one specific case—doped) that is lattice-matched to the substrate 1002. In some embodiments, substrate 1002 may also act as lower contact layer 1004. A first absorber layer 1006 is formed above the lower contact layer 1004, and also includes a III-V semiconductor material lattice-matched to the substrate 1002. A metamorphic buffer 1008, configured according to an embodiment of the invention, is then formed overlying the first absorber layer 1006. The metamorphic buffer layer structurally transitions the lattice constant from the first lattice constant value of substrate 1002 to a second desired lattice constant value that is lattice matched to that of the overlying semiconductor layer(s). A middle contact layer 1010 is then formed overlying the metamorphic buffer 1008 and includes a III-V semiconductor that has such second lattice constant. A second absorber layer 1012 is then formed overlying the middle contact layer 1010, and includes a III-V semiconductor that has the second lattice constant. A top contact layer 1014 is formed overlying second absorber 1012 and includes a III-V semiconductor material (in one specific case—doped) that has the second lattice constant. The example of the layered structure employed in FIG. 10 provides a situation when a doped layer of material is disposed adjacent to the layer of the optically-transparent metamorphic layer. In a specific case, such structure includes one doped material layer underlying the first light-absorbing material layer and another doped material layer overlying the second light-absorbing material layer.

Known in the art lithographic and etching steps can be employed to define mesa structures 1001 and 1003 within the semiconductor epitaxial layers. Standard lithographic and metallization steps can be used to form lower metal contact 1016, middle metal contact 1018, and top metal contact 1020, each in electrical contact with a respectively-corresponding contact layer of the contact layers 1004, 1010, and 1014. Passivation layers 1022 and 1024 can also be formed. An anti-reflection coating 1026 can also be formed on At least a portion of the top surface of top contact layer 1014 may be additionally coated with the anti-reflection (AR) coating 1026. These layers can be fabricated using standard lithography and deposition of dielectric materials.

The lower contact layer 1004 can be doped with a dopant of the first doping type (e.g. such as p-type), the middle contact layer 1010 can be doped with a dopant of the second doping type (e.g. such as n-type), and the top contact later 1014 can be doped with the dopant of the first doping type (e.g. such as p-type). In operation, photocurrent generated by the first absorber layer can be collected with the use of an appropriate electrical circuit (not shown) operably connected to metal contacts 1016 and 1018. Photocurrent generated by the second absorber layer can be collected in an appropriate electrical circuit (not shown) operably connected to metal contacts 1018 and 1020.

Other device configurations are also possible, for example a two-color detector with only two metal contacts, or a three-color detector with two, three or four metal contacts. Operation of such detectors can be controlled by a combination of different electrical connections to an external circuit, as well as through the use of carefully controlled biasing conditions in order to extract current absorbed in each of the different absorbing regions of a multicolor detector, as is known to one of ordinary skill in the art.

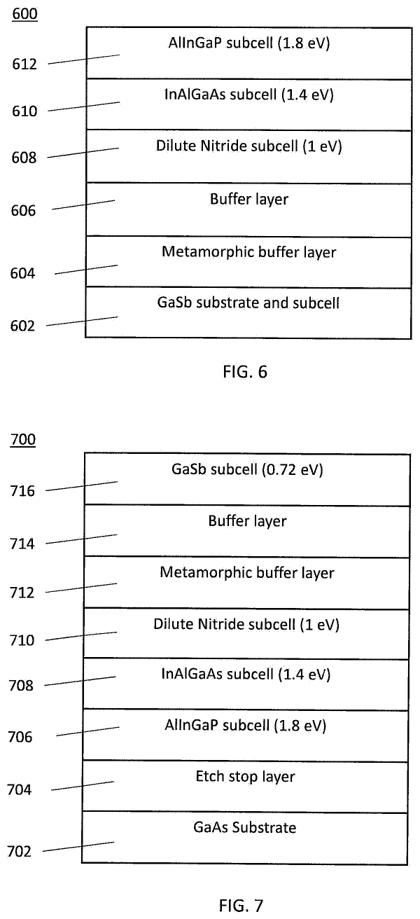

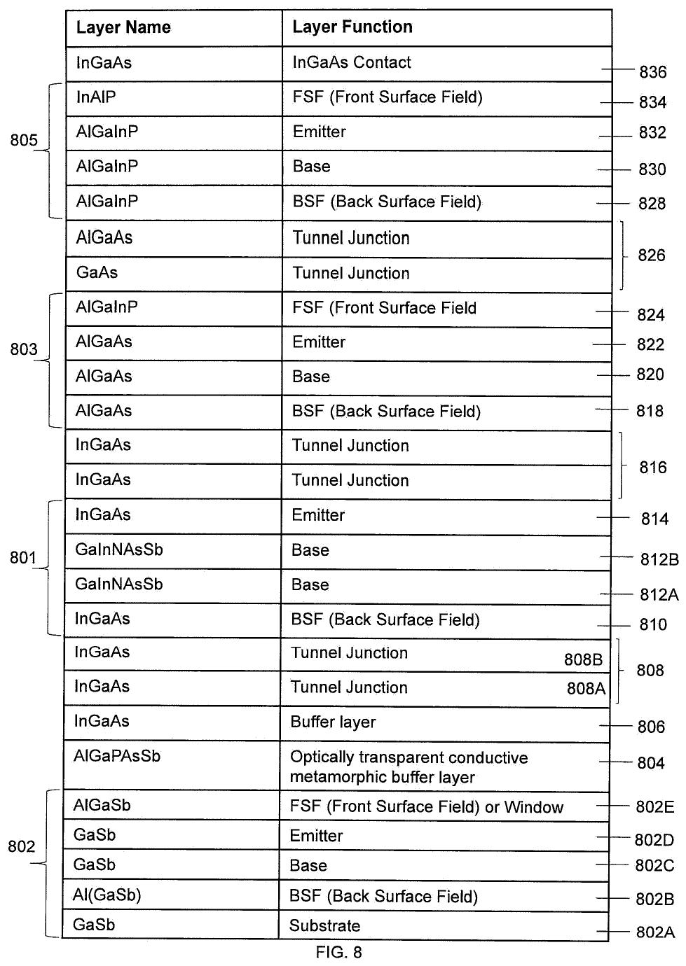

FIG. 6 shows a simplified cross section of a multijunction solar cell incorporating a GaSb-based subcell as the narrowest bandgap subcell. Generally, the term subcell is used herein to refer to a stack of layers containing a junction. A subcell is formed on GaSb substrate 602 by depositing a sequence of AlGaSb and GaSb layers that can form the back-surface field layer, the base, the emitter, and the front surface field or window layer. In some embodiments, a tunnel junction layer may also be formed on the subcell. However, this can also be formed above the metamorphic buffer layer. The purpose of a tunnel junction between subcells within a multijunction solar cell is to enable series connection between the different subcells, using only two contacts for the devices (a top contact, and a bottom contact). (The use of tunnel junctions is also shown in FIG. 8.)

After the GaSb-based cell is formed, a metamorphic buffer layer 604 is formed. In one embodiment, metamorphic buffer 604 comprises AlPSb, However, it can comprise GaPSb, AlGaPSb, AlAsSb, GaAsSb and/or AlGaAsSb. The metamorphic buffer layer is optically-transparent to light that is absorbed by GaSb subcell 602. The metamorphic buffer layer 604 is grown to provide for a transition of the lattice constant from that of GaSb to a second (in this case—smaller in value) lattice constant. In the example shown, metamorphic buffer 606 transitions a lattice constant approximately equal to that for GaAs or Ge. An optional buffer layer 606 is then grown. The buffer layer 606 can comprise InGaAs or GaAs and can include a tunnel junction.

A dilute nitride subcell 608 is then fabricated overlying the buffer layer 606 (or metamorphic buffer 604, in case when the buffer layer 606 is not present). Subcell 608 can have a bandgap between about 0.9 eV and 1.1 eV. The dilute nitride subcell can comprise GaₓIn₁₋ₓN_{y}As_{1-y-z}Sb_{z}, wherein the values for x, y, and z lie in the ranges 0≤x≤0.24, 0.001≤y≤0.07, and 0.001≤z≤0.2, and the thickness of the base layer of the dilute nitride cell can be between about 0.5 micron and 4 microns. Examples of dilute nitride materials and structures suitable for solar cells are disclosed in U.S. 2010/0319764, U.S. Pat. Nos. 8,912,433, 8,962,993, 9,214,580, U.S. 2017/0110613, and U.S. 2017/0213922, the disclosure of each of which is incorporated by reference herein. Dilute nitride sub-cells having graded doping profiles are disclosed in U.S. Pat. No. 9,214,580, U.S. 2016/0118526, and U.S. 2017/0338357, the disclosure of each of which is incorporated herein by reference. These dilute nitride base layers may include intentionally-doped region(s) with thicknesses between 0.4 microns and 3.5 microns, and with p-type doping levels between 1×10¹⁵ cm⁻³ and 1×10¹⁹ cm⁻³, and further contain an intrinsic (or unintentionally doped) diluted nitride layer or an intentionally doped dilute nitride layer with a constant dopant concentration, having a thickness from 0.1 microns and about 1 micron. The subcell is shown as a single layer. However, it will be understood that subcell 608 comprises multiple layers, including back surface field, base, emitter, front-surface filed and window layers. A subcell 610 including GaAs, InGaAs or InAlGaAs is then formed overlying dilute nitride subcell 608. The nominal bandgap for subcell 610 is chosen to be about 1.4 eV (and, more generally, according to the idea of the invention, within a range from about 1.3 eV to about 1.5 eV).

A subcell 612 comprising AlInGaP is then formed overlying subcell 210. The nominal bandgap for this subcell is about 1.8 eV, although other bandgap widths are within the scope of the invention. Although the subcell 612 is shown as a single layer, it will be understood that subcell 610 comprises multiple layers, including back surface field, base, emitter, front-surface field, window and contact layers.

The subcells are interconnected using tunnel junctions (not shown, for simplicity of illustration) as will be understood by one of ordinary skill in the art.

FIG. 7 illustrates a simplified example of a cross-section 700 of a multijunction solar cell that incorporates a GaSb subcell as the narrowest-bandgap subcell. In this example, the process of growth of the structure is organized as “inverted” growth process, in which the shorter-wavelength absorption region is grown before the longer-wavelength absorption region is grown, analogously to the example of FIG. 5. In the embodiment 700, an etch stop layer 704 is formed on GaAs substrate 702. In some examples, the substrate is a Ge substrate, or a buffered Silicon substrate that has a lattice constant approximately equal to that of GaAs or Ge. Etch stop layer 704 comprises a layer that has a high etch selectivity with respect to the substrate and the overlying epitaxial layers. Examples of etch stop layers with a high etch selectivity to GaAs include InGaP and AlInP. The wide bandgap (1.8 eV) subcell 706 then overlies the etch-stop layer. Subcell 706 comprises multiple layers, and can include a contact layer, a window layer, an emitter layer, a base layer and a back-surface field layer. In one example, the contact layer is a GaAs or InGaAs layer and is directly adjacent to etch stop layer 704. The high etch selectivity between the contact layer and the etch stop layer permits the substrate and etch stop layer to be removed by a sequence of mechanical lapping and/or chemical etch steps after the epitaxial growth of all layers has been completed, and the epitaxial stack bonded or adhered to a carrier or surrogate substrate.

Subcell 708 overlies subcell 706, and subcell 710 overlies subcell 708. Subcell 706 is an InGaAs, GaAs or InAlGaAs subcell, and subcell 710 is a dilute nitride subcell, as described in the previous example.

A metamorphic buffer layer 712 is then formed overlying subcell 710. In one embodiment, metamorphic buffer 712 comprises AlPSb. (In related embodiments, the buffer 712 can be configured to include GaPSb, AlGaPSb, AlAsSb, GaAsSb and/or AlGaAsSb.) The metamorphic buffer layer 712 is optically-transparent to light that is absorbed by an overlying GaSb subcell 714. Metamorphic buffer layer 712 I judiciously configured to transition the lattice constant from that of GaAs (or Ge) to a second (in this case—larger in value) lattice constant. In the example shown, metamorphic buffer 712 transitions a lattice constant approximately equal to that of GaSb. An optional buffer layer 714 is then formed overlying metamorphic buffer layer 712. The buffer layer 714 can contain GaSb or AlSb.

The layered structure of the device 700 is completed by forming a GaSb subcell 716 overlying the buffer layer 714. The GaSb subcell includes GaSb, AlGaSb and InGaSb layers devised to provide optical absorption and associated electrical and optical functions (such as a contact layer) in the GaSb subcell.

FIG. 8 shows, in more detail, the cross section of a multijunction solar cell of the example 600 of FIG. 6. A p-doped GaSb substrate 802A is cleaned to remove native oxides prior to epitaxial deposition. Epitaxial growth of a p-doped AlGaSb back-surface field layer 802B, a p-doped GaSb base layer 802C, an n-doped GaSb emitter layer 802D and an (optional) n-doped AlGaSb front-surface field or window layer 802E completes the GaSb subcell 802, which has a bandgap of approximately 0.72 eV.,

A metamorphic buffer layer 804 can then be epitaxially grown over GaAs substrate (and subcell) 802. The metamorphic buffer layer 804 can comprise AlPSb, GaPSb, AlGaPSb, AlAsSb, GaAsSb, AlGaAsSb, and/or AlGaPAsSb. The metamorphic buffer layer 804 is configured as discussed above to structurally change the lattice constant from that of GaSb (at the interface with the substrate 802) to that of GaAs or Ge (at the other surface of the buffer 804), and is transparent to wavelengths absorbed by the GaSb subcell 802. The thickness of the metamorphic buffer layer 804 is between about 0.5 microns and about 20 microns. A buffer layer 806 can then be (optionally) epitaxially grown over metamorphic buffer layer 804. The buffer layer 806 can comprise (In)GaAs. A (In)GaAs buffer layer can be, for example, from about 100 nm to about 900 nm thick in one implementation, from about 200 nm to about 800 nm thick in another implementation, or, alternatively from 300 nm to 700 nm thick, or from 400 nm to 600 nm thick. The buffer 806 can be optionally n-doped.

A tunnel junction 808 can then be epitaxially grown over the buffer layer 806. The tunnel junction 808, as shown in this example, includes two InGaAs layers, with the first layer 808A having a high n-type doping level, and the second layer 308A having a high p-type doping level. Typical compositions, thicknesses and doping levels required to form tunnel junctions are known in the art. For example, n-dopants can include Si, Se, and Te and n-type doping levels can range from 1×10¹⁹ cm⁻³ to 2×10²⁰ cm⁻³. P-type dopants can include Be and C, and doping levels greater than about 1×10¹⁹ cm⁻³ and up to 2×10²⁰ cm⁻³ can be used. Thicknesses for the doped layers in tunnel junctions can be between about 5 nm and 40 nm.

A sub-cell 801 (referred to as “J3”) is then epitaxially deposited on the tunnel junction 808. The sub-cell 801 contains a p-doped InGaAs back surface field layer 810, a p-doped GaInNAsSb base layer 812A, an intrinsic or unintentionally doped base layer 812B and an n-doped InGaAs emitter layer 814. The p-doped layer 812A and layer 812B can include, individually, Ga₁₋ₓInₓN_{y}As_{1-y-z}Sb_{z}, with 0≤x≤0.24, 0.001≤y≤0.07 and 0.001≤z≤0.2, or with 0.08≤x≤0.24, 0.02≤y≤0.05 and 0.001≤z≤0.02, or with 0.07≤x≤0.18, 0.025≤y≤0.04 and 0.001≤z≤0.03, or with 0≤x≤0.4, 0<y≤0.07, and 0<z≤0.04. The p-doped base layer 812A can have a spatially-graded doping profile, with the doping level decreasing from the interface with back surface field 810 to the interface with base layer 812B. The doping in base layer 812B can be graded exponentially between 1×10¹⁹ cm³ and 1×10¹⁵ cm⁻³, for example between 1×10¹⁸ and 5×10¹⁵ cm⁻³, or between 2×10¹⁷ and 7×10¹⁵ cm⁻³, where the minimum doping level is greater than or equal to the background doping level of the layer. The base layer 812B can be an intrinsic layer or an unintentionally doped layer, with a background doping concentration less than about 1×10¹⁶ cm⁻³ or less than about 5×10¹⁵ cm⁻³ or less than about 1×10¹⁵ cm³. Base layer 812B can also be doped at a fixed doping level of 1×10¹⁶ cm⁻³ or less. The sub-cell 801 can have an overall thickness between about 0.5 micron and about 4 microns.

A following tunnel junction 816, as shown, can then be epitaxially grown over the sub-cell 801, to include two InGaAs layers (one with high p-type doping, the other with high n-type doping). Typical compositions, thicknesses and doping levels used to form tunnel junctions are known in the art. For example, typical n-dopants include Si, Se, and Te and n-type doping levels can range between 1×10¹⁹ cm⁻³ and up to 2×10²⁰ cm⁻³. P-type dopants include C and doping levels greater than 1×10¹⁹ cm⁻³ and up to 2×10²⁰ cm⁻³ can be used. Thicknesses for the doped layers in tunnel junctions can be between about 5 nm and about 40 nm.

A sub-cell 803 (referred to as “J2”) is then epitaxially formed on the tunnel junction 816. The sub-cell 803 comprises an Al-containing back surface field layer 818. In embodiments formed with hybrid growth methodologies, the back surface field layer 818 can also be configured as a hydrogen barrier or gettering layer. While FIG. 8 shows layer 818 as a single layer, it is understood that back surface field layer 818 may include more than one material layer. When the layer 818 is configured to operate as a hydrogen barrier, the layer 818 comprises Al. For example, layer 818 can comprise AlGaAs, or InAlP and can be lattice-matched or pseudomorphically-strained to the substrate. The thickness of layer 818 can be, for example, between 100 nm and 5 microns. In some embodiments, layer 818 can comprise an Al-containing layer capped by a layer of GaAs, InGaAs or InGaP, having a thickness, for example, between 1 nm and 50 nm, or between 2 nm and 10 nm, or between 2 nm and 5 nm.

After the growth of layer 818, sub-cell 803 is completed by deposition of base layer 820, emitter layer 822, and front surface field layer 824. A tunnel junction 826 is then epitaxially grown. Typical compositions, thicknesses and doping levels used to form tunnel junctions are known in the art. By way of example, tunnel junction 826 is shown comprising a GaAs layer and an AlGaAs layer. However, it will be understood that other materials may be used. For example, the tunnel junction may comprise an InGaP layer and/or an AlGaAs layer. Examples of n-dopants for the tunnel junction layers include Si, Se, and Te and n-type doping levels in a range between 1×10¹⁹ cm⁻³ and up to 2×10²⁰ cm⁻³ can be used. P-type dopants can include C and doping levels in a range between 1×10¹⁹ cm⁻³ and up to 2×10²⁰ cm⁻³ can be used. Thicknesses for the doped layers in tunnel junctions can be between 5 nm and 40 nm. Sub-cell 805 (J1) is then epitaxially grown, depositing in sequence back surface field layer 828, base layer 830, emitter layer 832, front surface field layer 834, and contact layer 836. The contact layer can comprise GaAs or InGaAs. A top metal contact (not shown) can be deposited or formed over a first portion of the top surface of contact layer 836, and an anti-reflection coating (ARC) can be deposited or formed over a second portion of the top surface of contact layer 836. A bottom metal contact (not shown) can be deposited or formed over the back surface of substrate 802A.

A practitioner skilled in the art would readily appreciate that, in comparison with the provided examples, other types of material layers may be present or omitted in a semiconductor device such as a multicolor detector or a photovoltaic cell configured according to an embodiment of the invention, to create a functional device and are not necessarily described here in detail. These other types of materials include, for example, coverglass, anti-reflection coating (ARC), electrical-contact layers, front surface field (FSF) layer(s), tunnel junctions, optical window(s), an emitter, back surface field (BSF) layer(s), nucleation layers, buffer layers, barrier layers, reflector layers and a substrate or wafer handle. In particular, for a photovoltaic cell, cap or contact layer(s), ARC layers and electrical contacts (also denoted as the metal grid) can be formed above the top subcell, and buffer layer(s), the substrate or handle, and bottom contacts can be formed or be present below the bottom subcell 802. Multicolor photodetectors and multijunction photovoltaic cells may also be formed without one or more of the layers listed above. Each of these layers requires careful design to ensure that its incorporation into a multicolor photodetector or a multijunction photovoltaic cell does not impair their high performance.

To fabricate semiconductor optoelectronic and solar devices provided by the present disclosure, a plurality of layers can be deposited on a substrate in a first materials deposition chamber. The plurality of layers may include etch stop layers, release layers (i.e., layers designed to release the semiconductor layers from the substrate when a specific process sequence, such as chemical etching, is applied), contact layers such as lateral conduction layers, buffer layers, or other semiconductor layers. For example, the sequence of layers deposited can be a buffer layer(s), then a release layer(s), and then a lateral conduction or contact layer(s). Next the substrate can be transferred to a second materials deposition chamber where one or more junctions are deposited on top of the existing semiconductor layers. The substrate may then be transferred to either the first materials deposition chamber or to a third materials deposition chamber for deposition of one or more junctions and then deposition of one or more contact layers. Tunnel junctions are also formed between the junctions.

The movement or repositioning/relocation of the substrate and semiconductor layers from one materials deposition chamber to another chamber is referred to as transfer. For example, a substrate can be placed in a first materials deposition chamber, and then the buffer layer(s) and the bottom junction(s) can be deposited. Then the substrate and semiconductor layers can be transferred to a second materials deposition chamber where the remaining junctions are deposited. The transfer may occur in vacuum, at atmospheric pressure in air or another gaseous environment, or in any environment in between. The transfer may further be between materials deposition chambers in one location, which may or may not be interconnected in some way, or may involve transporting the substrate and semiconductor layers between different locations, which is known as transport. Transport may be done with the substrate and semiconductor layers sealed under vacuum, surrounded by nitrogen or another gas, or surrounded by air. Additional semiconductor, insulating or other layers may be used as surface protection during transfer or transport, and removed after transfer or transport before further deposition.

For example, a dilute nitride junction can be deposited in a first material deposition chamber, and the (Al)(In)GaP and (Al)(In)GaAs junctions can be deposited in a second material deposition chamber, with tunnel junctions formed between the junctions. A transfer occurs in the middle of the growth of one junction, such that the junction has one or more layers deposited in one materials deposition chamber and one or more layers deposited in a second materials deposition chamber.

To fabricate photonic devices discussed herein, some or all of the layers of the dilute nitride junctions and the tunnel junctions can be deposited in one materials deposition chamber by molecular beam epitaxy (MBE), and the remaining layers of the solar cell can be deposited by chemical vapor deposition (CVD) in another materials deposition chamber. For example, a substrate can be placed in a first materials deposition chamber and layers that may include nucleation layers, buffer layers, emitter and window layers, contact layers and tunnel junctions can be grown on the substrate, followed by one or more dilute nitride junctions. If there is more than one dilute nitride junction, then a tunnel junction is grown between adjacent junctions. One or more tunnel junction layers may be grown, and then the substrate can be transferred to a second materials deposition chamber where the remaining solar cell layers are grown by chemical vapor deposition. In certain embodiments, the chemical vapor deposition system is a MOCVD system. In a related embodiment, a substrate is placed in a first materials deposition chamber and layers that may include nucleation layers, buffer layers, emitter and window layers, contact layers and a tunnel junction are grown on the substrate by chemical vapor deposition. Subsequently, the top junctions, two or more, are grown on the existing semiconductor layers, with tunnel junctions grown between the junctions. Part of the topmost dilute nitride junction, such as the window layer, may then be grown. The substrate is then transferred to a second materials deposition chamber where the remaining semiconductor layers of the topmost dilute nitride junction may be deposited, followed by up to three more dilute nitride junctions, with tunnel junctions between them.

In some embodiments, a surfactant, such as Sb or Bi, may be used when depositing any of the layers of the device. A small fraction of the surfactant may also incorporate within a layer.

A semiconductor device comprising a dilute nitride layer can be subjected to one or more thermal annealing treatments after growth. For example, a thermal annealing treatment includes the application of a temperature in a range from about 400° C. to about 1,000° C. for a duration between about 10 microseconds and about 10 hours. Thermal annealing may be performed in an atmosphere that includes air, nitrogen, arsenic, arsine, phosphorus, phosphine, hydrogen, forming gas, oxygen, helium, or any combination of the preceding materials. In certain embodiments, a stack of junctions and associated tunnel junctions may be annealed prior to fabrication of additional junctions.

The invention as recited in claims appended to this disclosure is intended to be assessed in light of the disclosure as a whole, including features disclosed in prior art to which reference is made.

For the purposes of this disclosure and the appended claims, the use of the terms “substantially”, “approximately”, “about” and similar terms in reference to a descriptor of a value, element, property or characteristic at hand is intended to emphasize that the value, element, property, or characteristic referred to, while not necessarily being exactly as stated, would nevertheless be considered, for practical purposes, as stated by a person of skill in the art. These terms, as applied to a specified characteristic or quality descriptor means “mostly”, “mainly”, “considerably”, “by and large”, “essentially”, “to great or significant extent”, “largely but not necessarily wholly the same” such as to reasonably denote language of approximation and describe the specified characteristic or descriptor so that its scope would be understood by a person of ordinary skill in the art. In one specific case, the terms “approximately”, “substantially”, and “about”, when used in reference to a numerical value, represent a range of plus or minus 20% with respect to the specified value, more preferably plus or minus 10%, even more preferably plus or minus 5%, most preferably plus or minus 2% with respect to the specified value. As a non-limiting example, two values being “substantially equal” to one another implies that the difference between the two values may be within the range of +1-20% of the value itself, preferably within the +1-10% range of the value itself, more preferably within the range of +1-5% of the value itself, and even more preferably within the range of +1-2% or less of the value itself. The term “substantially equivalent” may be used in the same fashion.

The use of these terms in describing a chosen characteristic or concept neither implies nor provides any basis for indefiniteness and for adding a numerical limitation to the specified characteristic or descriptor. As understood by a skilled artisan, the practical deviation of the exact value or characteristic of such value, element, or property from that stated falls and may vary within a numerical range defined by an experimental measurement error that is typical when using a measurement method accepted in the art for such purposes.

Although specific embodiments have been illustrated and described herein, it will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present invention includes any other applications in which embodiment of the above structures and fabrication methods are used. The scope of the embodiments of the present invention should be determined with reference to claims associated with these embodiments, along with the full scope of equivalents to which such claims are entitled.

1. A semiconductor structure comprising:
a first light-absorbing material layer having a first bandgap, a first lattice constant, and a first absorption spectrum, wherein the first light-absorbing material layer absorbs first light;
an optically-transparent metamorphic buffer layer overlying the first light-absorbing material layer, the optically-transparent metamorphic buffer layer having a lattice constant; and
a second light-absorbing material layer overlying the optically-transparent metamorphic buffer layer and having a second bandgap, a second lattice constant, and a second absorption spectrum, wherein the second light-absorbing material layer absorbs second light;
wherein the optically-transparent metamorphic buffer layer is transparent to the first light or the second light.

2. The semiconductor structure of claim 1, wherein the optically-transparent metamorphic buffer layer is transparent to both the first light and the second light.

3. The semiconductor structure of claim 1, further comprising a third light-absorbing material layer, separated from the optically-transparent metamorphic buffer layer by either the first light-absorbing material layer or the second light-absorbing material layer, wherein the third light-absorbing material layer absorbs third light,
wherein the optically-transparent metamorphic buffer layer is transparent to the first light, the second light, and the third light.

4. The semiconductor structure of claim 1, wherein the semiconductor structure comprises at least two group V elements.

5. The semiconductor structure of claim 1,
wherein a lattice constant of the optically-transparent metamorphic buffer layer from a first value to a second value,
wherein the first value is substantially equal to the first lattice constant and the second value is not equal to the first value.

6. The semiconductor structure of claim 5, wherein the first light-absorbing material layer, the second light-absorbing material layer, and an auxiliary buffer layer is adjacent to the optically-transparent metamorphic buffer layer and forms an interface with the optically-transparent metamorphic buffer layer.

7. The semiconductor structure of claim 6, wherein:
the auxiliary buffer layer and the first light-absorbing material layer are adjacent to one another and form an interface therebetween, or
the auxiliary buffer layer and the second light-absorbing material layer are adjacent to one another and form an interface therebetween.

8. The semiconductor structure of claim 1, devoid of layers that are bonded to one another.

9. The semiconductor structure of claim 1, further comprising:
a doped layer adjacent to the optically-transparent metamorphic buffer layer.

10. The semiconductor structure of claim 1, wherein the optically-transparent metamorphic buffer layer is doped.

11. The semiconductor structure of claim 1, wherein the optically-transparent metamorphic buffer layer comprises:
an upper surface;
a lower surface; and
a plurality of sublayers between the upper and lower surfaces,
wherein different sublayers, of the plurality of the sublayers, are characterized by different contents of one or more group V elements.

12. The semiconductor structure of claim 1, further comprising:
a first doped material layer underlying the first light-absorbing material layer; and
a second doped material layer overlying the second light-absorbing material layer.

13. The semiconductor structure of claim 12, wherein the first doped material layer contains an n-type dopant, and the second doped material layer contains a p-type dopant.

14. The semiconductor structure of claim 12, wherein the first doped material layer contains a p-type dopant, and the second doped material layer contains an n-type dopant.

15. The semiconductor structure of claim 1, wherein the optically-transparent metamorphic buffer layer is doped with a dopant of the same type as a type of a dopant contained in a doped material layer that is immediately adjacent to the optically-transparent metamorphic buffer layer.

16. The semiconductor structure of claim 1, wherein the optically-transparent metamorphic buffer layer comprises a plurality of layers, wherein adjacent ones of the plurality of layers have at least one of different material compositions or different thicknesses.

17. The semiconductor structure of claim 16, wherein the plurality of layers of the optically-transparent metamorphic buffer layer comprises AlPSb, GaPSb, AlAsSb, GaAsSb, or AlGaPAsSb.

18.-21. (canceled)

22. An optically-transparent semiconductor metamorphic buffer layer comprising:
a lattice constant that changes from a first value to a second value,
wherein the first value is substantially equal to a first lattice constant, the first lattice constant being a lattice constant of a first layer of material, the first layer of material underlying the optically-transparent semiconductor metamorphic buffer layer,
wherein the second value is not equal to the first value.

23. The optically-transparent semiconductor metamorphic buffer layer of claim 22, wherein at least one of the following conditions is satisfied:
a) the optically-transparent semiconductor metamorphic buffer layer is optically-transparent to light absorbed by the first layer; or
b) the optically-transparent semiconductor metamorphic buffer layer includes at least two group V elements.

24. The optically-transparent semiconductor metamorphic buffer layer of claim 22, further comprising:
upper and lower surfaces; and
a plurality of sublayers between the upper and lower surfaces,
wherein different sublayers, of the plurality of the sublayers, are characterized by a different content of one or more group V elements.

25. The optically-transparent semiconductor metamorphic buffer layer of claim 22, further comprising:
i) a plurality of sublayers defining at least one digital alloy; and
ii) at least two group V elements.

26. The optically-transparent semiconductor metamorphic buffer layer of claim 24, wherein:
a first sublayer from the plurality of sublayers has a first average composition and a first thickness;
a second sublayer from the plurality of sublayers has a second average composition and a second thickness; and
a difference between the first and second average compositions is caused only by a difference between the first and second thicknesses.

27. The optically-transparent semiconductor metamorphic buffer layer of claim 24, wherein:
a first sublayer from the plurality of sublayers has a first average composition and a first material composition;
a second sublayer from the plurality of sublayers has a second average composition and a second material composition; and
a difference between the first and second average compositions is caused only by a difference between the first and second material compositions.

28. The optically-transparent semiconductor metamorphic buffer layer of claim 24,
wherein a first sublayer from the plurality of sublayers has a first average composition, a first thickness, and a first material composition,
wherein a second sublayer from the plurality of sublayers has a second average composition, a second thickness, and a second material compositions, and
wherein a difference between the first and second average compositions is caused by both a difference between the first and second thicknesses and a difference between the first and second material compositions.

29. The optically-transparent semiconductor metamorphic buffer layer of claim 22, further comprising:
upper and lower surfaces; and
a plurality of sublayers throughout the optically-transparent semiconductor metamorphic buffer layer in a direction transverse to the optically-transparent semiconductor metamorphic buffer layer,
wherein the optically-transparent semiconductor metamorphic buffer layer is characterized by cut-off wavelengths of absorption of the plurality of sublayers,
wherein a maximum value among the cut-off wavelengths of absorption corresponds to a sublayer, of the plurality of the sublayers, that is spatially separated from each of the upper and lower surfaces.

30. The optically-transparent semiconductor metamorphic buffer layer according to claim 22, comprising at least two group V elements.
